(19) United States
(12) Patent Application Publication
(10) Pub. No.: US 2026/0341628 A1
(43) Pub. Date: Oct. 29, 2026

(54) POROUS, POLYMER-BASED SUBSTRATES USED IN CELL CULTURES AND MICROSCOPY AND METHODS OF FORMING SAME

(71) Applicant: The Research Foundation for the State University of New York, Albany, NY (US)

(72) Inventors: Haixin Sui, Albany, NY (US); Yubing Xie, Albany, NY (US); Dipayan Sarkar, Albany, NY (US); Adam Koplas, Albany, NY (US); Julia Garrison, Albany, NY (US); Natalya Tokranova, Albany, NY (US); Yanfeng Zhang, Albany, NY (US)

(21) Appl. No.: 19/663,087

(22) Filed: Apr. 29, 2026

Related U.S. Application Data
(60) Provisional application No. 63/796,503, filed on Apr. 29, 2025.

(51) Int. Cl. H01J 37/20; G01N 21/64; G02B 21/16; H01J 37/26

(52) U.S. Cl. CPC H01J 37/20; G01N 21/64; G02B 21/16; H01J 37/26

(57) ABSTRACT

Porous, polymer-based substrates used for preparing and/or imaging samples including cell cultures are disclosed. The substrates include a patterned body formed from a photo-definable material, including, but not limited to, photo-definable polymer material. The patterned body of the substrates include a plurality of openings extending through the patterned body, and a border portion surrounding the plurality of openings. The patterned body also includes a plurality of patterning partitions formed within the border portion, where the plurality of patterning partitions defines at least a portion of the plurality of openings. Additionally, the patterned body includes a plurality of indexer features formed integral with at least a portion of the plurality of patterning partitions. Each of the plurality of indexer features extend into at least one of the plurality of openings extending through the patterned body.

### CROSS-REFERENCE TO RELATED APPLICATION

This application claims the benefit of U.S. Provisional Patent Application No. 63/796,503, filed Apr. 29, 2025, the entirety of which is hereby incorporated herein by this reference.

### GOVERNMENT RIGHTS

This invention was made with government support under Grant No. R01GM152716 awarded by the National Institutes of Health. The government has certain rights in the invention.

### BACKGROUND

The disclosure relates generally to polymer-based substrates, and more particularly, to porous, substrates formed from photo-definable materials that facilitate cell cultures and ease of microscopy imaging, as well as methods of forming the porous, polymer-based substrates.

Fluorescence light microscopy and electron microscopy (EM) are two complementary imaging approaches for studying biological samples at different spatial scales and resolutions. Fluorescence microscopy enables the visualization of specific molecules or structures within cells using fluorescent labels, providing high specificity and the ability to observe dynamic processes in living or fixed samples. In contrast, electron microscopy offers much higher spatial resolution by using electron beams rather than light, revealing ultrastructural details at the nanometer scale but typically requires fixed, dehydrated, and heavily processed specimens. Correlative light and electron microscopy (CLEM) combines the strengths of both techniques by allowing researchers to first locate and characterize the dynamic behavior of objects or regions of interest using fluorescence microscopy and then examine the same objects or regions at high resolution with EM, thereby bridging functional and structural information.

Conventional glass coverslips, commonly used in fluorescence microscopy, pose challenges for the EM component in CLEM studies. Cell samples grown or mounted on coverslips must be processed (such as fixation and staining), resin-embedded, removed from the glass, then cut thin to allow the electron beam to penetrate, and transferred to EM-compatible substrates, such as EM grids covered with a thin non-permeable continuous film. The precise regions or objects of interest identified and characterized during fluorescence imaging must be tracked throughout the entire EM specimen preparation process, which is technically challenging without an easily visible feature or index pattern to locate them. Moreover, glass coverslips are impermeable and are not suitable for studying cells that require growth on a cell culture system comprising a porous membrane support configured to permit molecular exchange between an upper and lower chamber.

Porous membranes, including, but not limiting to commercially available ones, widely used for cells that require growth on a permeable support structure, allow bidirectional exchange of nutrients and signaling molecules, enable cell polarization, and facilitate physiological cell behaviors and barrier function, etc. However, these porous membranes are not ideal for light microscopy due to their opacity and strong fluorescence background. Without an easily visible feature or index pattern, it is challenging to image, locate and track the objects or region of interest in cells grown on these porous membrane.

Meanwhile, conventional metal-based EM finder grids, often used to locate the object of interest in EM of solid materials, are not designed for CLEM studies of cells, although efforts have been made to use them in such studies. These finder grids are often not cell-culture-friendly, even after coatings with various extracellular-matrix components, and the metal grids must be removed before the resin-embedded blocks of cell samples are serially sectioned by ultramicrotome for EM specimen preparation. Removing the metal grids in a resin-embedded block can be technically challenging. The process of cutting or detaching grid materials can damage surrounding regions, disrupt sample orientation, or lead to partial sample loss, reducing reproducibility.

These limitations highlight the need for improved substrates that are compatible across imaging modalities without requiring a disruptive intermediate step (e.g., complete substrate removal).

### BRIEF DESCRIPTION

A first aspect of the disclosure provides a substrate for at least one of preparing or imaging samples. The substrate includes: a patterned body formed from a photo-definable polymer material, the patterned body including: a plurality of openings extending through the patterned body; a border portion surrounding the plurality of openings; a plurality of patterning partitions formed within the border portion, the plurality of patterning partitions defining at least a portion of the plurality of openings; and a plurality of indexer features formed integral with at least a portion of the plurality of patterning partitions, each of the plurality of indexer features extending into at least one of the plurality of openings extending through the patterned body.

A second aspect of the disclosure provides a method of forming a substrate for at least one of preparing or imaging samples. The method includes: coating a wafer with a photo-definable polymer material; soft baking the wafer coated with the photo-definable polymer material; and exposing the photo-definable polymer material to an ultraviolet light to form a patterned body within the photo-definable polymer material, the patterned body including: a plurality of openings; a border portion surrounding the plurality of openings; a plurality of patterning partitions formed within the border portion, the plurality of patterning partitions defining at least a portion of the plurality of openings; and a plurality of indexer features formed integral with at least a portion of the plurality of patterning partitions, each of the plurality of indexer features extending into at least one of the plurality of openings extending through the patterned body.

A third aspect of the disclosure provides a substrate including: a patterned body formed from a photo-definable polymer material, the patterned body including: a plurality of openings extending through the patterned body; a border portion surrounding the plurality of openings; a plurality of patterning partitions formed within the border portion, the plurality of patterning partitions defining at least a portion of the plurality of openings; and a plurality of indexer features formed integral with at least a portion of the plurality of patterning partitions, each of the plurality of indexer features extending into at least one of the plurality of openings extending through the patterned body; and a perforated polymeric support film deposited directly over a surface of the patterned body, the perforated polymeric support film facilitating cell cultures within the patterned body.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure, taken in conjunction with the accompanying drawings that depict various embodiments of the disclosure, in which:

FIG. 1 shows a top view of a photo-definable polymer-based substrate for preparing and/or imaging samples, including cell cultures, according to embodiments of the disclosure.

FIG. 2 shows a side view of the substrate shown in FIG. 1, according to embodiments of the disclosure.

FIG. 3 shows an enlarged, top view of a portion of the substrate shown in FIG. 1 taken along reference line 3-3, according to embodiments of the disclosure.

FIGS. 4 and 5 show enlarged, top views of portions of distinct substrates, according to additional embodiments of the disclosure.

FIG. 6 shows a top view of a photo-definable polymer-based substrate for preparing and/or imaging samples including cell cultures, according to another embodiment of the disclosure.

FIG. 7 shows an enlarged, top view of portions of another photo-definable polymer-based substrate including breakaway areas, according to further embodiments of the disclosure.

FIG. 8 shows a top view of a photo-definable polymer-based substrate including a plurality of predetermined regions included therein, according to additional embodiments of the disclosure.

FIG. 9 shows a schematic view of a sample including cell cultures deposited over a perforated polymeric support film and/or a photo-definable polymer-based substrate, according to embodiments of the disclosure.

FIG. 10 shows a schematic view of the sample, the perforated polymeric support film, and the photo-definable polymer-based substrate of FIG. 9 undergoing a fluorescence light microscopy (LM) imaging process, according to embodiments of the disclosure.

FIG. 11A shows a fluorescence light microscopy (LM) image of a portion of the sample including cell cultures, the perforated polymeric support film, and substrate of FIG. 9, according to embodiments of the disclosure.

FIG. 11B shows a fluorescence light microscopy (LM) image of a portion of the sample and the photo-definable polymer-based substrate of FIG. 9 (e.g., excluding the perforated polymeric support film), according to embodiments of the disclosure.

FIG. 12 shows a schematic view of the sample and the photo-definable polymer-based substrate of FIG. 9 encased in epoxy resin, according to embodiments of the disclosure.

FIG. 13 shows a micrograph image of the sample, the perforated polymeric support film, and the photo-definable polymer-based substrate encased in the epoxy resin of FIG. 12, according to embodiments of the disclosure.

FIG. 14 shows a schematic view of segments of the sample, the perforated polymeric support film, and the photo-definable polymer-based substrate of FIG. 12 prepared for additional processing (e.g., electron microscopy (EM)), according to embodiments of the disclosure.

FIG. 15 shows a flow chart illustrating processes of forming a photo-definable polymer-based substrate utilized for preparing and/or imaging samples including cell cultures, according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to polymer-based substrates, and more particularly, to porous, substrates formed from photo-definable materials that facilitate cell cultures and ease of microscopy imaging, as well as methods of forming the porous, polymer-based substrates.

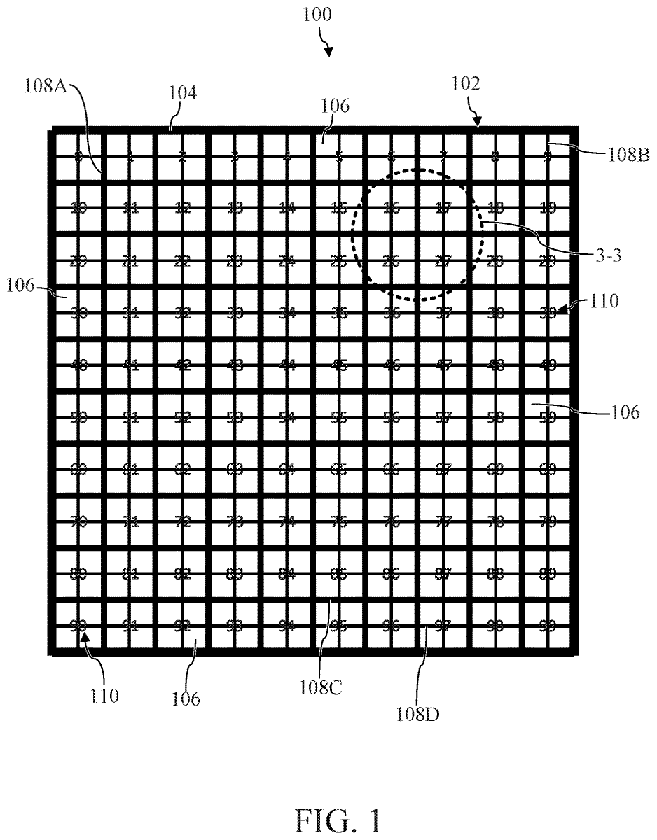

These and other embodiments are discussed below with reference to FIGS. 1-15. However, those skilled in the art will readily appreciate that the detailed description given herein with respect to these Figures is for explanatory purposes only and should not be construed as limiting.

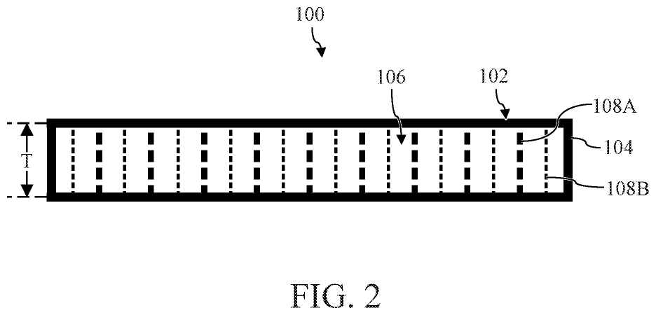

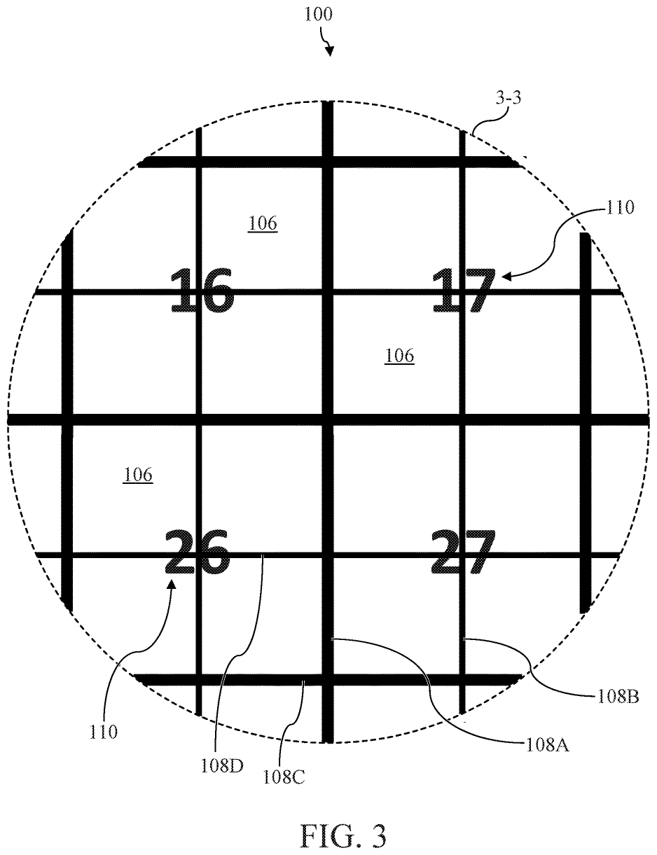

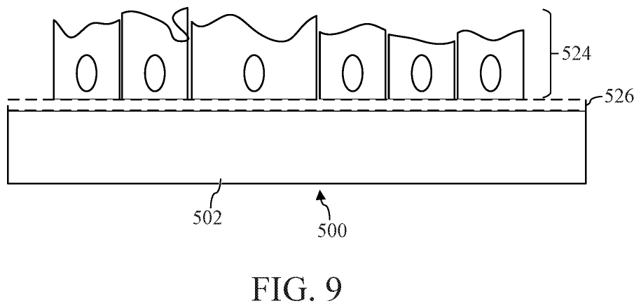

FIGS. 1-3 show various views of a polymer-based substrate 100 that is configured to aid in both supporting cell cultures and indexing cell cultures for purposes of imaging, as discussed herein. More specifically, FIG. 1 shows a top view of substrate 100, FIG. 2 shows a side view of substrate 100, and FIG. 3 shows an enlarged, top view of a portion 3-3 of the substrate as identified in FIG. 1. As discussed herein, substrate 100 is used in various processes for cell culture, indexing/sample identification, imaging, etc. For example, substrate 100 can be used in place of and/or can replace conventional objects such as porous membranes, including, but not limited to, conventional cell culture inserts, conventional transwell trays, or conventional filter membranes typically used during various cell cultures and imaging processes, including fluorescence light microscopy (LM), electron microscopy (EM), or correlative light and electron microscopy (CLEM) (see, FIGS. 9-13).

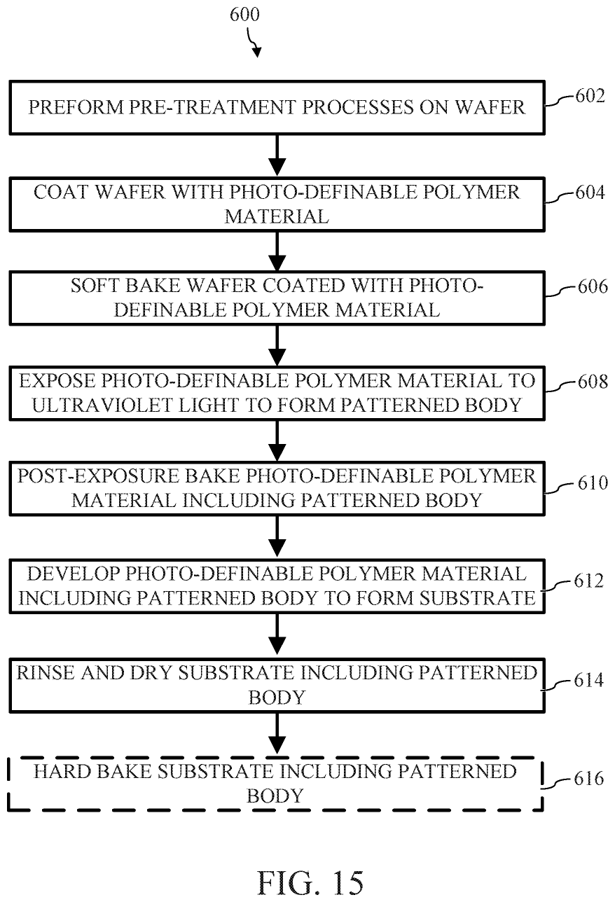

In exemplary embodiments, substrate 100 is formed from a photo-definable polymer material. That is, substrate 100, and the various features included therein, are formed as a single, unitary, and/or monolithic component that is formed, at least in part, from a photo-definable polymer material. Photo-definable polymer material used to form substrate 100 includes various material properties and/or characteristics that facilitate improved performance and/or support for cell cultures and/or improved indexing and/or imaging of samples when utilizing substrate 100. For example, the material used to form substrate 100 includes any photo-definable polymer that is capable of and/or lends itself to versatile fabrication techniques with adjustability in fabrication (e.g., customizable thickness, density, porosity, elasticity), and desired mechanical properties including high crosslinking, high yield strengths, and increased flexibility. Additionally, the photo-definable polymer materials used to form substrate 100 have desired characteristics and/or properties including high optical transparency (e.g., transparent above 400 nanometers (nm)), biocompatibility with various cells and organisms to sustain cell growth and viability, and chemical and thermal stability post processing (see, FIG. 15) to ensure the preservation of substrate 100 and the various features included therein during cell culture/indexing/imaging. Furthermore, material used to form substrate 100 includes any photo-definable polymer that includes desired cutting or segmenting properties that are less than cutting and segmenting properties of conventional instruments (e.g., metal TEM finder grid components), and/or are substantially similar to cutting or segmenting properties for epoxy resins that are deposited over substrate 100 during sample preparation and/or imaging as discussed herein. Moreover, the photo-definable polymer materials used to form substrate 100 have desired characteristics and/or properties, including high permeability, perfusion compatibility, and more specifically desired permeability to bidirectional exchange of solutes and permit perfusion.

The photo-definable polymer material forming substrate 100 includes, but is not limited to, photoresists, photocurable polymers, photosensitive, photo-patternable coatings thin films, and the like. For example, the photo-definable polymer material can include any suitable polyimide material, including, but not limited to, photo-definable polyimides, thermally curable polyimides, polyimide thin films, and polyimide-based composite substrates. Alternatively, the photo-definable polymer material forming substrate 100 can include an epoxy-based negative photoresist, such as SU-8 photoresist material. In exemplary embodiments, distinct variants and/or forms of SU-8 photoresist material can be used to substrate 100, wherein the variant and/or form of SU-8 photoresist material is dependent, at least in part, on the processes used to form substrate 100, the size and/or dimensions (e.g., thickness, width, length) of substrate 100, and/or the intended use for substrate 100 (e.g., cell culture for sample, indexing, CLEM imaging, etc.). For example, SU-8 photoresist material used to form substrate 100 can include SUEX K20, SUEX K30, SUEX K50, or SUEX K100 variant formed as a dry film, or alternatively can include SU-8 3010, SU-8 TF 6010, SU-8 25, SU-8 2035, or SU-8 2050.

As shown in FIGS. 1-3, substrate 100, formed from photo-definable polymer material, includes a patterned body 102 including a plurality of features to facilitate cell cultures within a prepared sample and/or aid in indexing and/or imaging portions of substrate 100 that include cell cultures. For example, patterned body 102 of substrate 100 includes a grid formation. More specifically, patterned body 102 includes a border portion 104 defining the outer boundaries of substrate 100, and a plurality of openings 106 formed through patterned body 102. As shown in FIGS. 1-3 border portion 104 surrounds the plurality of openings 106, and defines at least a portion of the plurality of openings 106 included within patterned body 102 of substrate 100. Additionally as shown, each of the plurality of openings 106 are formed, extend, and/or are created through (e.g., in-and-out of page in FIG. 1) patterned body 102 of substrate 100 such that substrate 100 is permeable and/or porous. In the exemplary embodiment shown in FIG. 1, substrate 100 includes approximately 400 distinct openings 106 within patterned body 102. Although 400 openings 106 are shown, it is to be understood that substrate 100 can include any desired number of openings 106 to be formed therein. Additionally in the exemplary embodiment, each of the plurality of openings 106 included within substrate 100 and/or defined in patterned body 102 are substantially uniform and/or are formed to include substantially uniform dimensions and/or volumes when compared to one another. In non-limiting examples, each of the plurality of openings 106 extending through the patterned body 102 includes a volume between approximately 0.5 μm and approximately 500 μm, or between approximately 25 μm and approximately 475 μm, or between approximately 100 μm and approximately 400 μm, or approximately 150 μm and approximately 350 μm, or approximately 200 μm and 300 μm, or approximately 225 μm and approximately 275 μm. Each opening 106 formed in substrate 100 is sized, dimensioned, and/or is formed to include a substantially uniform volume to facilitate and/or improve cell cultures therein and/or within substrate 100. As discussed herein, distinct portions (e.g., indexer features) of substrate 100 extend into openings 106 formed thereon. This in turn may reduce and/or vary the volume of each opening 106 included within substrate 100. However, it is to be understood that the range of volumes indicated herein for openings 106 included in substrate 100 are provided as examples volume ranges and/or are provided to emphasize that the volume and/or dimensions of each opening 106 are substantially uniform and/or equal through substrate 100. In additional non-limiting examples, openings 106 included in patterned body 102 of substrate 100 can be non-uniform in dimension and/or volume.

In exemplary embodiments, patterned body 102 of substrate 100 also include a plurality of patterning partitions 108A, 108B, 108C, 108D formed within border portion 104. As shown in FIGS. 1-3, each of the plurality of patterning partitions 108A, 108B, 108C, 108D are formed integral with and extend between two opposing sidewalls forming border portion 104. More specifically, patterning partitions 108A, 108B are formed within substrate 100 parallel to one another, and extend perpendicular to and between two opposing sidewalls forming border portion 104. Additionally, patterning partitions 108C, 108D are formed within substrate 100 parallel to one another, and extend perpendicular to and between two distinct, opposing sidewalls forming border portion 104. As shown in FIGS. 1 and 3, patterning partitions 108C, 108D are also formed within patterned body 102 of substrate 100 substantially perpendicular to patterning partitions 108A, 108B. The plurality of patterning partitions 108A, 108B, 108C, 108D define at least a portion of the plurality of openings 106 included in patterned body 102 of substrate 100. That is, and in conjunction with border portion 104, the plurality of patterning partitions 108A, 108B, 108C, 108D define openings 106 formed within patterned body 102, and/or define a grid-like pattern within substrate 100, where openings 106 are separate and/or are deposited between each of the plurality of patterning partitions 108A, 108B, 108C, 108D. In exemplary embodiments where the dimensions and/or volume of each opening 106 are substantially uniform, a distance between each of the plurality of patterning partitions 108A, 108B, 108C, 108D is also uniform and/or substantially equal throughout patterned body 102 of substrate 100. In additional exemplary embodiments, the distance between at least two patterning partitions 108A, 108B, 108C, 108D can be different than the distance between distinct patterning partitions 108A, 108B, 108C, 108D.

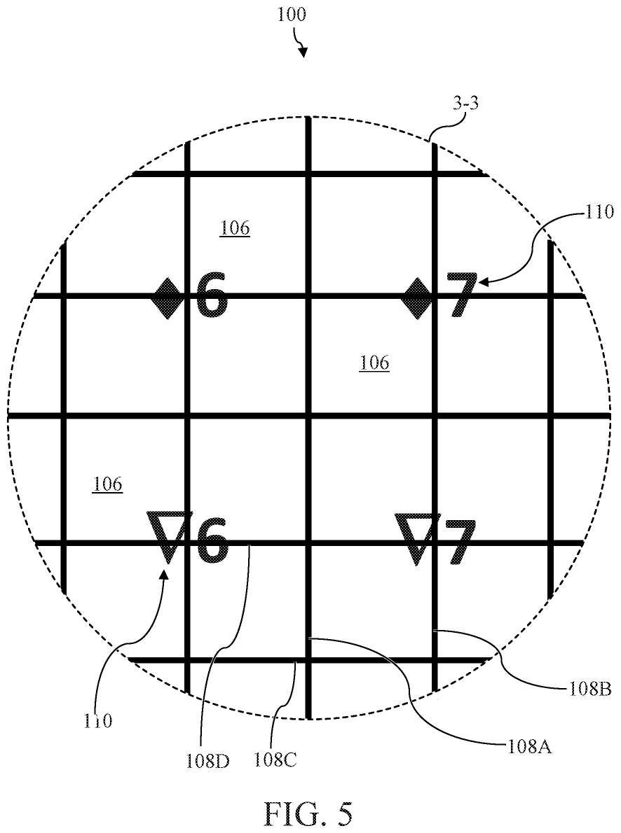

In the non-limiting examples shown in FIGS. 1-3, substrate 100 is formed such that the plurality of patterning partitions 108A, 108B, 108C, 108D include distinct dimensions and/or material thicknesses. More specifically, patterning partitions 108A, 108C are formed within patterned body 102 of substrate 100 to include a first dimension or material thickness, and distinct patterning partitions 108B, 108D are formed within patterned body 102 to include a second, distinct dimension or material thickness. In the exemplary embodiment, the first dimension or material thickness of patterning partitions 108A, 108C are greater than the second dimension or material thickness of patterning partitions 108B, 108D. Substrate 100 is formed to include patterning partitions 108A, 108B, 108C, 108D having distinct material thicknesses to increase mechanical properties and/or characteristics of substrate 100 during operation. In alternative exemplary embodiments (see e.g., FIG. 5), each of the plurality of patterning partitions 108A, 108B, 108C, 108D are formed within substrate 100 to include uniform dimensions and/or material thicknesses.

Patterned body 102 of substrate 100 also includes a plurality of indexer features 110 formed integral and/or monolithically with at least a portion of the plurality of patterning partitions 108A, 108B, 108C, 108D. For example, and as shown in FIGS. 1 and 3, indexer features 110 are formed integrally at each intersection of patterning partitions 108B, 108D within substrate 100. Each of the plurality of indexer features 110 are also formed within patterned body 102 of substrate 100 between and/or adjacent to patterning partitions 108A, 108C. In exemplary embodiments, each of the plurality of indexer features 110 also extend into at least one of the plurality of openings 106 extending through patterned body 102. Briefly turning to FIG. 3, at least a portion of each of the plurality of indexer features 110, displayed as numeric symbols (e.g., “16,” “17,”, “26,” “27”) and formed integral with patterning partitions 108B, 108D, extending into at least one opening 106 formed within patterned body 102 and/or defined by patterning partitions 108A, 108B, 108C, 108D within substrate 100. The plurality of indexer features 110 are included within patterned body 102 of substrate 100 to aid in indexing and/or identifying portions of substrate 100 that include certain cell cultures and/or portions of sample that require segmenting for further analysis and/or imaging. In the exemplary embodiment shown in FIGS. 1 and 3, the plurality of indexer features 110 includes a plurality of sequential, numeric symbols, where each numeric symbol is associated with and/or identifies a predetermined portion of substrate 100. However, it is to be understood that the plurality of indexer features 110 can formed as any series of symbols or characters that aid in indexing and/or identifying as discussed herein. In other exemplary embodiments, the plurality of indexer features 110 can include a plurality of alphabetic symbols, a plurality of geometric symbols, a plurality of graphical symbols, or any combination of symbols.

As discussed herein, substrate 100 is formed as a single, integral, and/or monolithic component. As such, each of the border portion 104, the plurality of patterning partitions 108A, 108B, 108C, 108D, and the plurality of indexer features 110 are all formed integral with one another and/or formed from the photo-definable polymer material as discussed herein.

FIG. 2 shows a side view of substrate 100 depicted in FIG. 1. In the exemplary embodiment shown, substrate 100 includes a predetermined thickness (T). The predetermined thickness of patterned body 102 for substrate 100 is dependent, at least in part, on the photo-definable polymer material used to form substrate 100 and/or the intended use for substrate 100, as similarly discussed herein. In exemplary embodiments, patterned body 102 of substrate 100 includes a thickness (T) between approximately 5 micrometers (μm) and approximately 100 μm. Alternatively, patterned body 102 of substrate 100 includes a thickness (T) between approximately 20 μm and approximately 85 μm, or approximately 35 μm and approximately 75 μm, or approximately 40 μm and approximately 70 μm, or approximately 50 μm and approximately 60 μm.

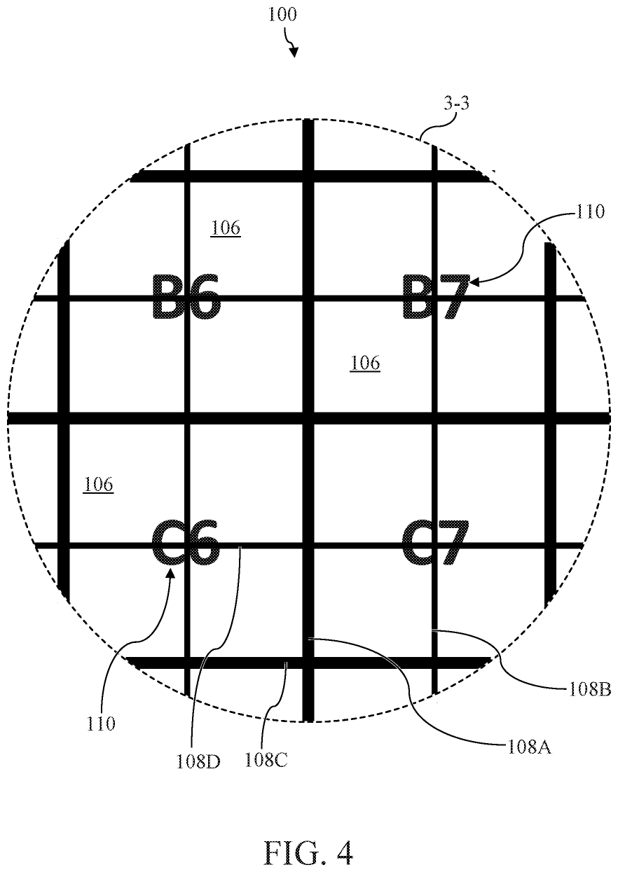

FIGS. 4 and 5 show additional, enlarged views of non-limiting examples of substrate 100 including a plurality of indexer features 110. It is understood that similarly numbered and/or named components may function in a substantially similar fashion. Redundant explanation of these components has been omitted for clarity.

In the exemplary embodiment shown in FIG. 4, the plurality of indexer features 110 include a plurality of alpha-numeric symbols (e.g., “B6,” “B7,”, “C6,” “C7”) formed integral with patterning partitions 108B, 108D, and extending into at least one opening 106 formed within patterned body 102. In the embodiment, the first alphabetic symbol identifies a specific row of patterned body 102 within substrate 100, while the second, numeric symbol identifies and/or corresponds to a specific column for patterned body 102. The rows and columns can be defined by and/or between patterning partitions 108A, 108C. For example, indexer feature 110 displayed as “B6” identifies four (4) openings 106 within the second (2^{nd}) row, and sixth (6^{th}) column of patterned body 102 for substrate 100.

In the exemplary embodiment shown in FIG. 5, the plurality of indexer features 110 include a plurality of geometric-numeric symbols (e.g., “♦6,” “♦7,”, “∇6,” “∇7”) formed integral with patterning partitions 108B, 108D, and extending into at least one opening 106 formed within patterned body 102. In the embodiment, the first geometric symbol identifies a specific row of patterned body 102 within substrate 100, while the second, numeric symbol identifies and/or corresponds to a specific column for patterned body 102. For example, indexer feature 110 displayed as “♦6” identifies four (4) openings 106 within the second (2^{nd}) row, and sixth (6^{th}) column of patterned body 102 for substrate 100.

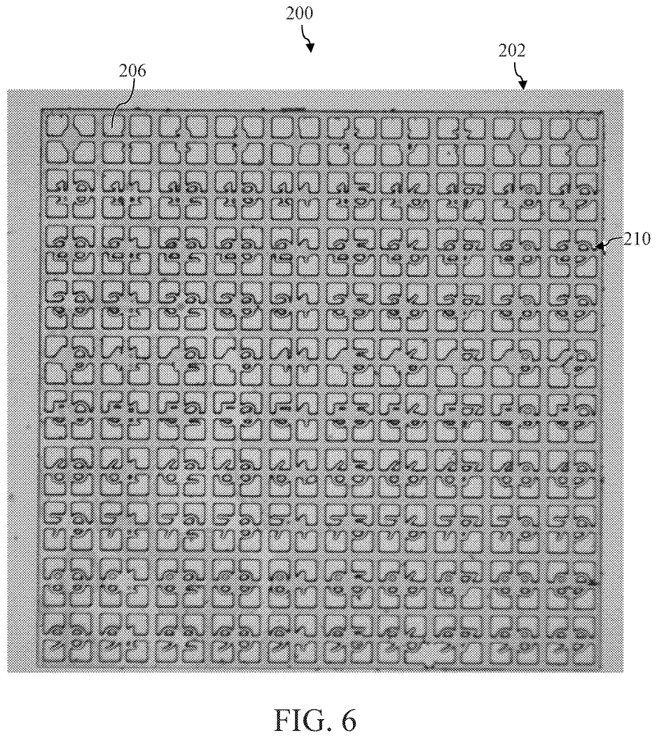

FIG. 6 shows top view of another substrate 200 created using processes discussed herein with respect to FIG. 15. In the exemplary embodiment, indexer features 210 are formed within patterned body 202 to be larger than those shown in FIGS. 1-5. As such, indexer features 210 extend further into openings 206 formed through patterned body 202 of substrate 200.

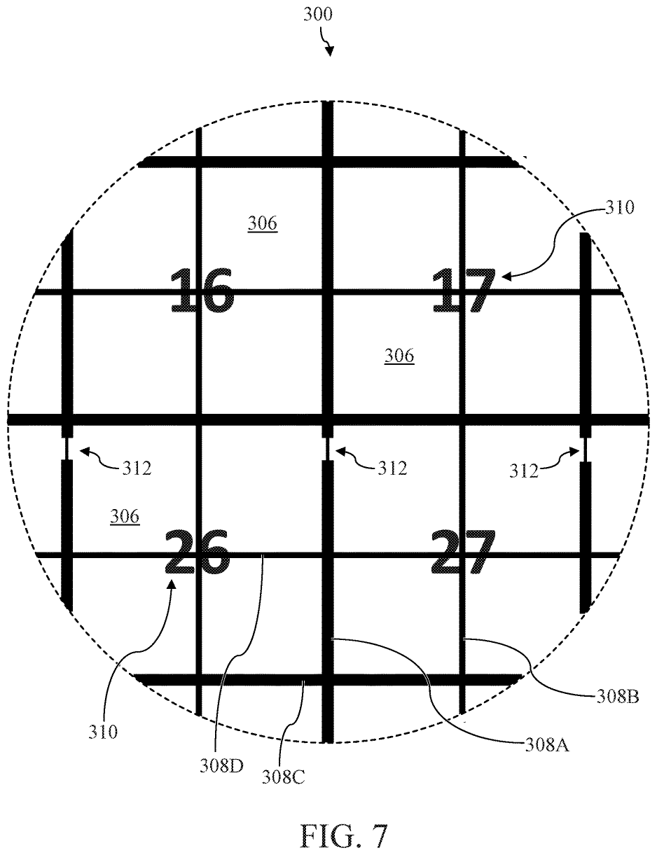

FIG. 7 shows enlarged portion of substrate 300 similar to portion of substrate 100 shown and discussed herein with respect to FIGS. 3-5. It is understood that similarly numbered and/or named components may function in a substantially similar fashion. Redundant explanation of these components has been omitted for clarity.

In exemplary embodiments, substrate 300 shown in FIG. 7 includes at least one breakaway areas 312 included therein. More specifically, at least one of the plurality of patterning partitions 308A, 308B, 308C, 308D included in patterned body 302 of substrate 300 includes breakaway areas 312. For example, each patterning partitions 308A includes at least one breakaway area 312 therein, where each breakaway area 312 is substantially aligned within patterned body 302 of substrate 300. Breakaway area 312 is formed and/or included within at least one of the plurality of patterning partitions 308A, 308B, 308C, 308D to improve and/or ease the cutting, breaking, and/or segmenting of substrate 300, as discussed herein during imaging and/or analysis procedures. In the non-limiting example shown in FIG. 7, breakaway areas 312 included in patterning partitions 308A includes and/or is formed as a reduced width of patterning partitions 308A. In other non-limiting examples, breakaway areas 312 included in patterning partitions 308A, 308B, 308C, 308D include and/or are formed as a reduced height of patterning partitions 308A, 308B, 308C, 308D, a reduced length of patterning partitions 308A, 308B, 308C, 308D, and/or a reduced material composition of patterning partitions 308A, 308B, 308C, 308D.

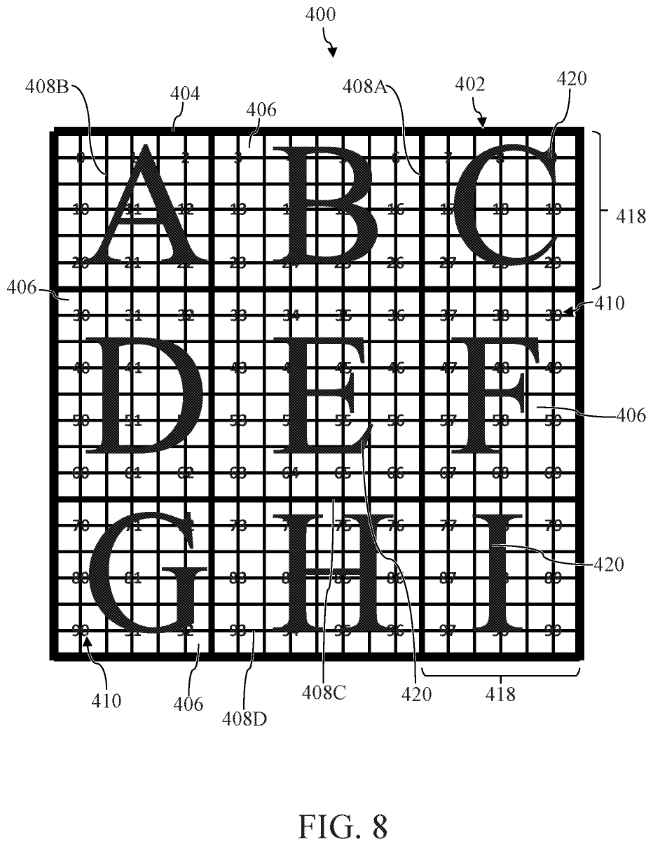

FIG. 8 shows top view of substrate 400 similar substrate 100 shown and discussed herein with respect to FIGS. 1-5. It is understood that similarly numbered and/or named components may function in a substantially similar fashion. Redundant explanation of these components has been omitted for clarity.

In the exemplary embodiment shown in FIG. 7, and distinct from substrate 100, substrate 400 includes a plurality of predetermined regions 418 defined border portion 404 and/or at least one patterning partition 408A, 408C of the plurality of patterning partitions 408A, 408B, 408C, 408D. That is, patterning partitions 408A, 408C formed in patterned body 402 of substrate 400 distinguish, define, and/or separate distinct predetermined regions 418 formed within substrate 400. In the non-limiting example shown in FIG. 7, substrate 400 includes nine (9) distinct regions 418, as defined by patterning partitions 408A, 408C. Each of the plurality of predetermined regions 418 also include and/or encompass a distinct group of openings of the plurality of openings 406 included within patterned body 402 of substrate 400.

Additionally, patterned body 402 of substrate 400 includes a plurality of region indicator symbols 420 formed integral with at least a portion of the plurality of patterning partitions 408A, 408B, 408C, 408D. That is, and substantially similar to indexer features 410, each predetermined region 418 included in substrate 400 also includes region indicator symbols 420 formed integral with patterning partitions 408A, 408B, 408C, 408D and utilized for indexing and/or identifying portions of substrate 400 that include certain cell cultures and/or portions of a sample that require segmenting for further analysis and/or imaging using substrate 400. Each of the plurality of region indicator symbols 420 are only formed within a single, predetermined region 418 between and/or adjacent to patterning partitions 408A, 408C defining predetermined regions 418. In exemplary embodiments, each of the plurality of region indicator symbols 420 also extend into and/or over at least one of the plurality of openings 406 extending through patterned body 402 and included in the corresponding group of openings formed with the predetermined region 418 of substrate 400. In the exemplary embodiment shown in FIG. 7, the plurality of region indicator symbols 420 include a plurality of sequential, alphabetic symbols, where each alphabetic symbol is associated with and/or identifies a distinct, predetermined region 418 of substrate 400. Although shown as being alphabetic, it is to be understood that the plurality of region indicator symbols 400 can formed as any series of symbols or characters that aid in indexing and/or identifying as discussed herein. In other exemplary embodiments, the plurality of region indicator symbols 420 can include a plurality of numeric symbols, a plurality of geometric symbols, a plurality of graphical symbols, or any combination of symbols.

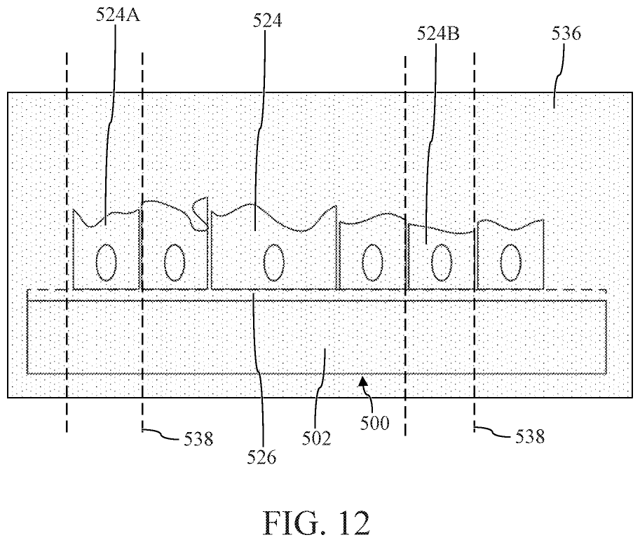

FIGS. 9-14 shows substrate 500 utilized in performing various processes involving a cell culture sample 524. More specifically, FIGS. 9-11B depict substrate 500 used in growing and imaging cell cultures 524 on and/or within substrate 500, while FIGS. 12-14 depict substrate 500 and cell cultures 524 undergoing cutting or segmenting for additional imaging and/or processing. Substrate 500 shown and discussed herein with respect to FIGS. 9-14 is substantially similar to substrate 100 discussed herein with respect to FIGS. 1-5. It is understood that similarly numbered and/or named components may function in a substantially similar fashion. Redundant explanation of these components has been omitted for clarity.

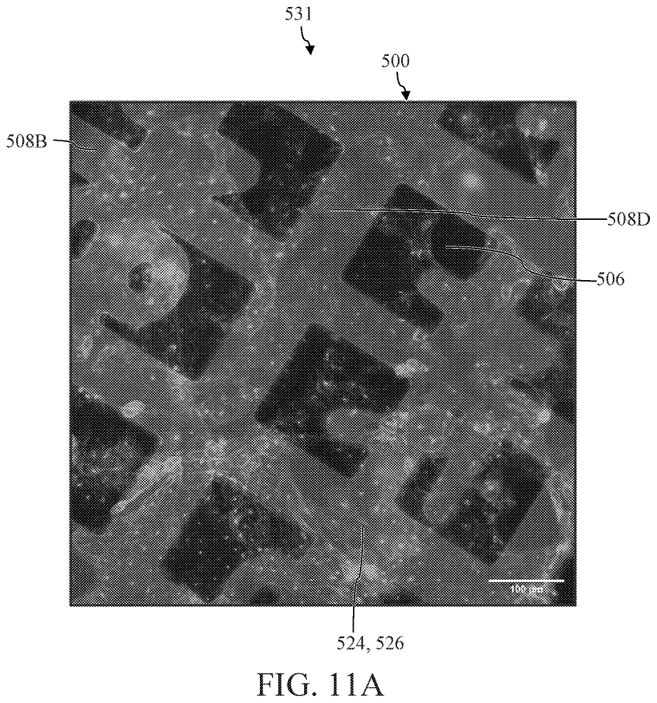

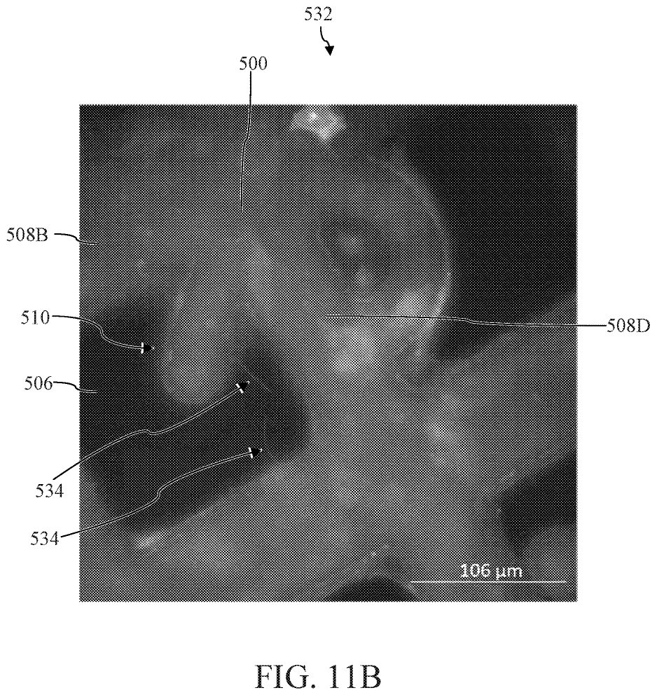

In the exemplary embodiment shown in FIG. 9, and prior to depositing cell cultures 524 onto substrate 500, to facilitate cell culture therein and/or thereon, substrate 500 can be coated with a perforated polymeric support film 526 (hereafter, “film 526”)(shown in phantom as optional) to aid in supporting cell growth into a confluent cell layer or support cell culture in a manner similar to porous membrane support (see, FIG. 11A). For example, film 526 includes, but not limited to, a lacey formvar film, lacey carbon film, lacey polymer films, holey polymer films, perforated polymer films, discontinuous polymer support films, mesh-like polymer membranes. Furthermore, film 526 is formed from any suitable material, chemical, and/or chemical compound including, but not limited to, polylysine, gelatin, fibronectin, or Matrigel. In the non-limiting example shown, film 526, shown in phantom as optional, is deposited and/or formed over a first surface of substrate 500, and/or substantially encompasses at least a portion of patterned body 502 of substrate 500. Additionally, and as discussed herein, film 526 may also act as a barrier and/or intermediary layer between cell cultures 524 and substrate 500. In other exemplary embodiments, film 526 may not be deposited and/or formed over substrate 500 (see, FIG. 11B). In this example, cell cultures 524 are deposited, disposed, and/or positioned directly on substrate 500 and undergo similar processes (e.g., cell culturing) as discussed herein.

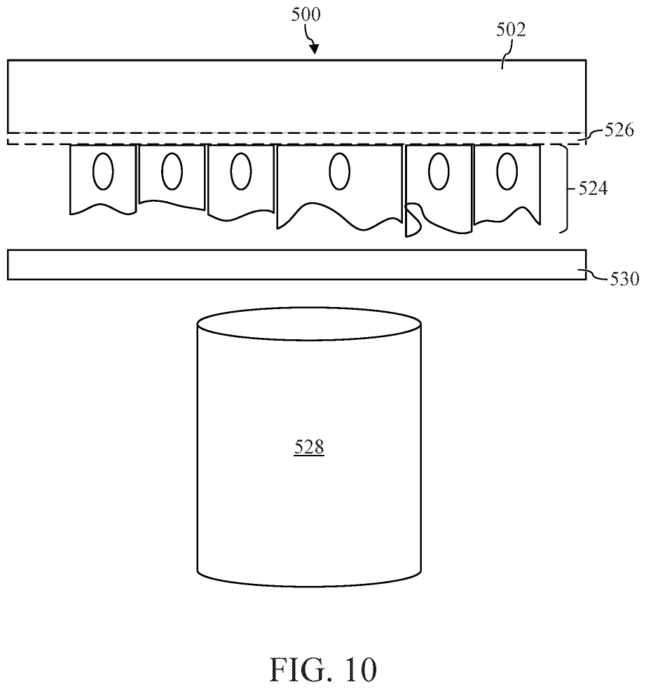

As shown in FIG. 9, a plurality of cell cultures 524 are deposited over substrate 500 to facilitate and/or support cell cultures 524 within and/or on substrate 500, prior to performing imaging processes to view cell cultures 524. More specifically, cell cultures 524 are deposited over, deposited in, and/or contact film 526, directly adjacent substrate 500. As discussed herein, the imaging processes performed using substrate 500 include, but are not limited to, fluorescence light microscopy (LM), electron microscopy (EM), or correlative light and electronic microscopy (CLEM). In the non-limiting examples discussed herein with respect to FIGS. 9-11A, cell cultures 524 are being prepared using substrate 500 and film 526 for the purposes of performing fluorescence light microscopy (LM) (see, FIGS. 10-11A). Additionally, in the exemplary embodiments, cell cultures 524 can include a cellular structure for an organism, bacteria, yeast, or mammalian cells, including, but not limited to, primary cells, cell lines, stem cells, or differentiated cells.

FIGS. 10, 11A, and 11B show substrate 500 and cell cultures 524, and/or film 526 undergoing a fluorescence light microscopy (LM). Specifically, FIG. 10 shows substrate 500, film 526 (shown in phantom as optional), and cell cultures 524, subsequent to the passing of a growth period (e.g., approx. 24 hours-72 hours) being positioned within and/or adjacent to a fluorescence light microscopy device 528 and an intermediary glass layer 530 for imaging. FIG. 11A depicts a fluorescence light microscopy (LM) image 531 of epithelial cells grown on substrate 500 coated with and/or including film 526 formed thereon. In the exemplary image 531, cell cultures 524 formed within film 526 on substrate 500 are formed, for example, as a confluent cell layer and/or a continuous layer of cells for imaging and/or identifying, as discussed herein.

Additionally, FIG. 11B also depicts a fluorescence light microscopy (LM) image 532 captured using fluorescence light microscopy (LM) device 528. In the exemplary embodiment, image 532 depicts a portion of substrate 500 and cell cultures 524 deposited and/or formed directly on substrate 500. That is, substrate 500 captured in image 532 does not include film 526, and therefore, cell cultures 524 are formed directly on outer surfaces of substrate 500. As shown in FIG. 11B, image 532 captured by device 528 depicts, for example, primary cilia 534 included therein. More specifically, and by way of example, fluorescence light microscopy (LM) image 532 captured using fluorescence light microscopy (LM) device 528 depicts a portion of substrate 500 including primary cilia 534 derived from cell cultures 524 and grown directly within opening 506 of formed in substrate 500.

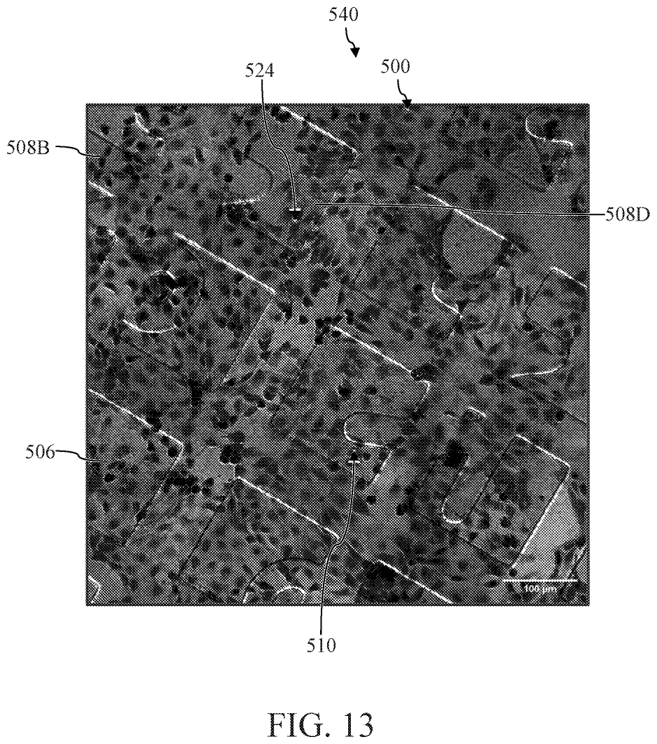

Subsequent to cell cultures 524 on and/or within substrate 500, substrate 500 is encased in an epoxy resin 536, as shown in FIG. 12. Encasing substrate 500 and cell cultures 524 included therein and/or thereon with epoxy resin 536, ensures that cell cultures 524 remain in the same location on substrate 500, as identified during the fluorescence light microscopy (LM) imaging process (e.g., FIGS. 10-11B). For example, FIG. 13 shows an micrograph image 540 of the sample including cell cultures 524, film 526, and substrate 500 encased in epoxy resin 536, as shown in FIG. 12. More specifically, image 540 depicts cell cultures 524 on substrate 500 subsequent to staining, resin-embedding, ready for ultramicrotomy. As shown, cell cultures 524 remain preserved and detectable in image 540 by performing processes discussed herein and/or utilizing substrate 500 (and film 526, where applicable) in preparing and/or supporting cell cultures 524 for subsequent imaging (e.g., electron microscopy (EM) imaging).

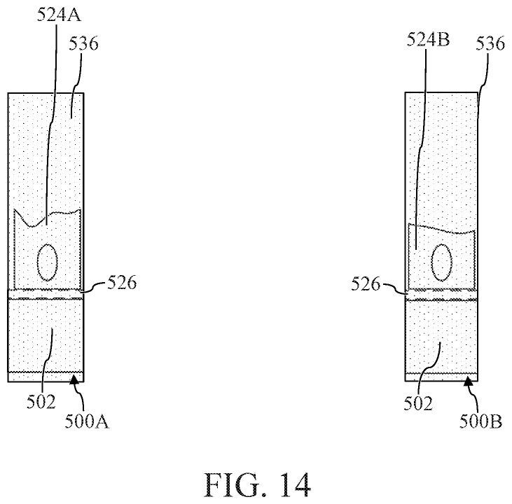

Furthermore, encasing substrate 500 and cell cultures 524 with epoxy resin allows for additional processes to be performed on substrate 500 and cell cultures 524. For example, cell cultures 524 identified within substrate 500 using openings 506, pattern partitions 508A, 508B, 508C, 508D, and indexer features 510 (see, FIGS. 11A and 11B), as shown in image 532, are segmented for further inspection and imaging-such as electron microscopy (EM), imaging. Briefly returning to FIG. 12, cut or segmentation lines 538 are determined, identified, and/or established to segment the desired cell cultures 524A, 524B formed on a portion substrate 500 that require additional processing (e.g., electron microscopy (EM) imaging). Distinct from conventional processes, and as a result of substrate 500 being formed from photo-definable polymer material having desired cut or segmentation properties and/or characteristics, each desired cell culture 524A, 524B is cut or segmented along with a portion of substrate 500A, 500B remaining after the segmentation (see, FIG. 13). That is, and as shown in FIG. 14, in preparing desired cell cultures 524A, 524B for further processing, a portion of epoxy resin 536 encasing desired cell cultures 524A, 524B, along with a portion of substrate 500A, 500B is segmented from the remainder of the sample. The segmented cell cultures 524A and 524B can then undergo the electron microscopy (EM) imaging process without the need to remove portions of substrate 500A, 500B. Additionally, and because substrate 500 remains in place during the segmentation and/or cutting process, desired cell cultures 524A, 524B previously identified, indexed, and/or located on substrate 500 using the features (e.g., 506, 508, 510) included therein, are more easily and more accurately cut or segmented for additional processing as discussed herein.

FIG. 15 shows a flow chart illustrating processes 600 of forming a substrate. More specifically, FIG. 15 shows processes 600 for forming a substrate from photo-definable polymer material for use in at least one preparing or imaging a sample of cell cultures.

In process 602, pre-treatment processes are performed on a wafer. That is, pre-treatment processes are performed on wafer in preparation for forming the substrate. In exemplary embodiments, the pre-treatment processes include cleaning the wafer using, for example, acetone or a combination of hydrogen peroxide (H₂O₂)+sulfuric acid (H₂SO₄), and subsequently drying the wafer using, for example, air of nitrogen (N₂). Additionally, the pre-treatment processes performed on the wafer include heating the wafer at a predetermined temperature (e.g., approximately 120 °C), for a predetermined period of time (e.g., approximately 15 minutes) before depositing a sacrificial release layer over the wafer, and baking the wafer including the deposited, sacrificial release layer.

In process 604, the wafer is coated with a photo-definable polymer material. More specifically, the wafer undergoes a spin coating process during process 604 to coat, form, and/or deposit the photo-definable polymer material onto the wafer. Photo-definable polymer material, including but not limited to, photoresists, photocurable polymers, photosensitive, photo-patternable coatings thin films, and the like, capable of being spun coat onto the wafer in process 604. For example, the photo-definable polymer material can include any suitable polyimide material including, but not limited to, photo-definable polyimides, thermally curable polyimides, polyimide thin films, and polyimide-based composite substrates. Alternatively, the photo-defendable polymer material can include an epoxy-based negative photoresist, such as SU-8 photoresist material. In exemplary embodiments, distinct variants of SU-8 photoresist material can include, but are not limited to, SUEX K20, SUEX K30, SUEX K50, SUEX K100, SU-8 3010, SU-8 TF 6010, SU-8 25, SU-8 2035, or SU-8 2050.

In process 606, the wafer coated with the photo-definable polymer material is soft baked. In exemplary embodiments, the wafer coated with the photo-definable polymer material is soft baked in two distinct stages and/or steps. First, the wafer and photo-definable polymer material are baked at a first temperature (e.g., approximately 65 °C) for a first period of time, and subsequently the wafer and photo-definable polymer material are baked at a second temperature (e.g., approximately 95 °C) for a second period of time. In the non-limiting example, the second temperature is greater than the first temperature during the soft baking process 606.

In process 608, the photo-definable polymer material is exposed to an ultraviolet (UV) light to form a patterned body within the photo-definable polymer material. More specifically, the photo-definable polymer material is exposed the UV light for a predetermined period of time and/or under at least one intensity for the working condition, in order to for the patterned body within the photo-definable polymer material. In exemplary embodiments, the patterned body formed within the photo-definable polymer material includes a plurality of openings, a border portion surrounding the plurality of openings, and a plurality of patterning partitions formed within the border portion. The plurality of patterning partitions define at least a portion of the plurality of openings. Additionally, the patterned body formed within the photo-definable polymer material includes a plurality of indexer features formed integral with at least a portion of the plurality of patterning partitions. Each of the plurality of indexer features extend into at least one of the plurality of openings extending through the patterned body.

The exposing of the photo-definable polymer material to the ultraviolet light to form the patterned body in process 608 further includes forming a breakaway area within at least one of the plurality of patterning partitions. In exemplary embodiments, the forming of the breakaway area include at least one a reduced height of the patterning partition, a reduced width of the patterning partition, a reduced length of the patterning partition, or a reduced material composition of the patterning partition. Additionally, or alternatively, the exposing of the photo-definable polymer material to the ultraviolet light to form the patterned body in process 608 further includes forming the patterned body to include a thickness (T) between approximately 5 micrometers (μm) and approximately 100 μm; and forming each of the plurality of openings extending through the patterned body to include a volume between approximately 0.5 μm and approximately 500 μm.

In process 610, the photo-definable polymer material including the patterned body is post-exposure baked. More specifically, and subsequent to the exposure in process 608, the photo-definable polymer material including the patterned body is baked again in process 610. Similar to the soft bake in process 606, the photo-definable polymer material including the patterned body is post-exposure baked in two distinct stages and/or steps. First, the wafer and the photo-definable polymer material including the patterned body are baked at a first temperature (e.g., approximately 65 °C) for a first period of time, and subsequently the wafer and the photo-definable polymer material including the patterned body are baked at a second temperature (e.g., approximately 95 °C) for a second period of time. In the non-limiting example, the second temperature is greater than the first temperature during the post-exposure baking process 610.

In process 612, the photo-definable polymer material including the patterned body formed therein is developed. More specifically, the wafer and the photo-definable polymer material including the patterned body are developed using and/or being submerged a developer solution. In exemplary embodiments, the developer used to develop the wafer and the photo-definable polymer material including the patterned body includes, but is not limited to, Polypropylene Glycol Monomethyl Ether Acetate (PGMEA). Additionally, the photo-definable polymer material and wafer are developed for an extended, predetermined amount of time. In exemplary embodiments, the photo-definable polymer material and wafer are developed overnight and/or for between approximately 4 hours and approximately 24 hours. The extended predetermined amount of time for developing the photo-definable polymer material and wafer ensures the photo-definable polymer is released from the wafer, to form the substrate from the photo-definable polymer material including the patterned body, as discussed herein.

In process 614, the developed photo-definable polymer material including the patterned body formed therein is rinsed and dried. More specifically, and subsequent to the development of the wafer and the photo-definable polymer material including the patterned body in process 612 to form the substrate (e.g., release or separation from the wafer), in process 614, the substrate formed from the photo-definable polymer material is rinsed using a solution and subsequently dried. In exemplary embodiments, the substrate is rinsed using isopropyl alcohol (IPA).

In process 616, shown in phantom as optional, the developed photo-definable polymer material including the patterned body formed therein is hard baked. That is, and subsequent to the rinsing and drying in process 614, in process 616, the substrate formed from the photo-definable polymer material and including the patterned body is hard baked for a predetermined temperature (e.g., between approximately 150 °C and approximately 200 °C), for a predetermined period of time (e.g., between approximately 15 minutes and approximately 30 minutes).

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A substrate for at least one of preparing or imaging samples, the substrate comprising:
a patterned body formed from a photo-definable polymer material, the patterned body including:
a plurality of openings extending through the patterned body;
a border portion surrounding the plurality of openings;
a plurality of patterning partitions formed within the border portion, the plurality of patterning partitions defining at least a portion of the plurality of openings; and
a plurality of indexer features formed integral with at least a portion of the plurality of patterning partitions, each of the plurality of indexer features extending into at least one of the plurality of openings extending through the patterned body.

2. The substrate of claim 1, wherein the photo-definable polymer material forming the patterned body includes a polyimide material.

3. The substrate of claim 1, wherein the photo-definable polymer material forming the patterned body includes SU-8 photoresist material.

4. The substrate of claim 1, wherein the patterned body includes a thickness (T) between approximately 5 micrometers (μm) and approximately 100 μm.

5. The substrate of claim 1, wherein each of the plurality of openings extending through the patterned body includes a volume between approximately 0.5 μm and approximately 500 μm.

6. The substrate of claim 1, wherein the plurality of indexer features includes at least one of:
a plurality of alphabetic symbols,
a plurality of numeric symbols,
a plurality of geometric symbols, or
a plurality of graphical symbols.

7. The substrate of claim 1, wherein the patterned body further includes:
a plurality of predetermined regions defined by at least one of the border portion or at least one patterning partition of the plurality of patterning partitions, each of the plurality of predetermined regions including a distinct group of openings of the plurality of openings; and
a plurality of region indicator symbols formed integral with at least a portion of the plurality of patterning partitions, the plurality of region indicator symbols identifying one of the plurality of predetermined regions.

8. The substrate of claim 1, wherein at least one of the plurality of patterning partitions includes a breakaway area having at least one of:
a reduced height of the patterning partition,
a reduced width of the patterning partition,
a reduced length of the patterning partition, or
a reduced material composition of the patterning partition.

9. The substrate of claim 1, wherein the patterned body is configured to be coated in a perforated polymeric support film to facilitate cell culture at least one of on or in the substrate.

10. A method of forming a substrate for at least one of preparing or imaging samples, the method comprising:
coating a wafer with a photo-definable polymer material;
soft baking the wafer coated with the photo-definable polymer material; and
exposing the photo-definable polymer material to an ultraviolet light to form a patterned body within the photo-definable polymer material, the patterned body including:
a plurality of openings;
a border portion surrounding the plurality of openings;
a plurality of patterning partitions formed within the border portion, the plurality of patterning partitions defining at least a portion of the plurality of openings; and
a plurality of indexer features formed integral with at least a portion of the plurality of patterning partitions, each of the plurality of indexer features extending into at least one of the plurality of openings extending through the patterned body.

11. The method of claim 10, further comprising:
post-exposure baking the photo-definable polymer material including the patterned body formed therein; and
developing the photo-definable polymer material including the patterned body formed therein for a predetermined period of time to form the substrate subsequent to the post-exposure baking of the photo-definable polymer material,
wherein the substrate is formed from the photo-definable polymer material and includes the patterned body.

12. The method of claim 11, further comprising rinsing the substrate formed from the photo-definable polymer material including the patterned body.

13. The method of claim 12, further comprising hard baking the substrate formed from the photo-definable polymer material including the patterned body subsequent to the rinsing.

14. The method of claim 10, further comprising:
performing pre-treatment processes on the wafer prior to the coating of the wafer with the photo-definable polymer material, the pre-treatment processes including:
cleaning the wafer;
drying the wafer;
heating the wafer;
depositing a sacrificial release layer over the wafer; and
baking the wafer including the deposited, sacrificial release layer.

15. The method of claim 10, wherein the photo-definable polymer material coating the wafer includes a polyimide material.

16. The method of claim 10, wherein the photo-definable polymer material coating the wafer includes SU-8 photoresist material.

17. The method of claim 10, wherein the exposing of the photo-definable polymer material to the ultraviolet light to form the patterned body further includes:
forming a breakaway area within at least one of the plurality of patterning partitions, the breakaway area including:
a reduced height of the patterning partition,
a reduced width of the patterning partition,
a reduced length of the patterning partition, or
a reduced material composition of the patterning partition.

18. The method of claim 10, wherein the exposing of the photo-definable polymer material to the ultraviolet light to form the patterned body further includes:
forming the patterned body to include a thickness (T) between approximately 5 micrometers (μm) and approximately 100 μm; and
forming each of the plurality of openings extending through the patterned body to include a volume between approximately 0.5 μm and approximately 500 μm.

19. A substrate comprising:
a patterned body formed from a photo-definable polymer material, the patterned body including:
a plurality of openings extending through the patterned body;
a border portion surrounding the plurality of openings;
a plurality of patterning partitions formed within the border portion, the plurality of patterning partitions defining at least a portion of the plurality of openings; and
a plurality of indexer features formed integral with at least a portion of the plurality of patterning partitions, each of the plurality of indexer features extending into at least one of the plurality of openings extending through the patterned body; and
a perforated polymeric support film deposited directly over a surface of the patterned body, the perforated polymeric support film facilitating cell cultures within the patterned body.

20. The substrate of claim 19, wherein:
the patterned body includes a thickness (T) between approximately 5 micrometers (μm) and approximately 100 μm, and
each of the plurality of openings extending through the patterned body include a volume between approximately 0.5 μm and approximately 500 μm.
